(19) United States
(12) Patent Application Publication
(10) Pub. No.: US 2013/0240882 A1
(43) Pub. Date: Sep. 19, 2013

(54) DIE, WAFER AND METHOD OF PROCESSING A WAFER

(71) Applicant: Dietrich Bonart, Bad Abbach (DE)

(72) Inventor: Dietrich Bonart, Bad Abbach (DE)

(73) Assignee: INFINEON TECHNOLOGIES AG, Neubiberg (DE)

(21) Appl. No.: 13/420,682

(22) Filed: Mar. 15, 2012

(51) Int. Cl. H01L 23/532; H01L 21/66

(52) U.S. Cl. 257/48; 257/741; 438/18; 257/E23.164; 257/E23.002; 257/E21.531

(57) ABSTRACT

A die in accordance with various embodiments may include a metallization area located proximate an edge of the die, and an electrical connection connected to the metallization area and running from the metallization area to the edge, wherein the electrical connection is free from metal. A wafer in accordance with various embodiments may include a die region having a metallization area, a kerf region having an electric or electronic device, and an electrical connection connecting the electric or electronic device with the metallization area, wherein the electrical connection is free from metal.

### BACKGROUND

Various embodiments relate generally to a die, a wafer and a method of processing a wafer.

Wafers may commonly be used in the fabrication of integrated circuits (ICs) or chips. A wafer may include a plurality of die regions or integrally-formed dies. The die regions or dies may be separated by a singulation process such as sawing. Singulation of the dies may also be referred to as dicing.

### SUMMARY

A die in accordance with various embodiments may include: a metallization area located proximate an edge of the die; an electrical connection connected to the metallization area and running from the metallization area to the edge, wherein the electrical connection is free from metal.

A wafer in accordance with various embodiments may include: a die region having a metallization area; a kerf region having an electric or electronic device; an electrical connection connecting the electric or electronic device with the metallization area, wherein the electrical connection is free from metal.

A method of processing a wafer in accordance with various embodiments may include: providing a wafer having a die region and a kerf region; forming an electric or electronic device in the kerf region; forming a metallization area in the die region; forming an electrical connection in or on the wafer connecting the electric or electronic device with the metallization area, the electrical connection being free from metal.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of various embodiments. In the following description, various embodiments are described with reference to the following drawings, in which:

FIG. 1 shows a schematic plan view of a wafer for illustrating various embodiments;

FIG. 2 shows an enlarged view of a section of a wafer;

FIG. 3 shows a schematic plan view of a section of a wafer in accordance with an embodiment;

FIG. 4 shows a diagram illustrating a method of processing a wafer in accordance with an embodiment;

FIG. 5A shows a schematic plan view of a die in accordance with an embodiment; and

FIG. 5B shows an enlarged view of section “B” in FIG. 5A.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments. Various embodiments are described in connection with devices, and various embodiments are described in connection with methods, however it is to be understood that embodiments described in connection with devices may apply to the methods as well, and vice versa.

Wafers may commonly be used in the fabrication of integrated circuits (ICs) or chips. A wafer may include a plurality of die regions or integrally-formed dies. The die regions or dies may be separated by a singulation process such as sawing. Singulation of the dies may also be referred to as dicing.

Usually, dicing will be carried out along so-called dicing streets (sometimes also referred to as sawing streets or scribe lines) running between the dies and may result in the removal of the wafer material and destruction of any structures located in those dicing streets. The region of a wafer that will be affected (e.g. destroyed) by the dicing may also be referred to as a kerf region of the wafer.

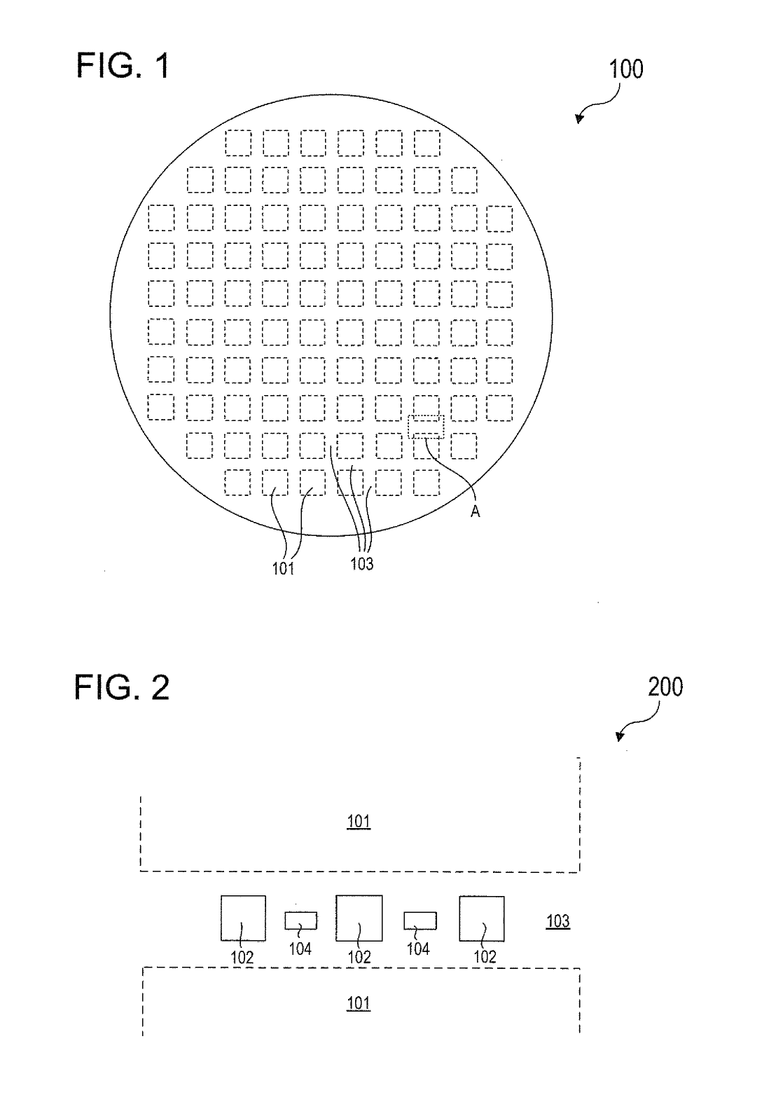

FIG. 1 shows a schematic plan view of a wafer 100 including a plurality of die regions 101 separated by a kerf region 103 located between the die regions 101. The number of die regions 101 may be arbitrary. As shown in FIG. 1, the die regions 101 may have a quadratic shape, however the die regions 101 may also have a rectangular shape, or any other shape in general. As shown in FIG. 1, the die regions 101 may be arranged in a rectangular array, however the die regions 101 may also be arranged differently. As shown in FIG. 1, the wafer 100 may have a circular shape, however the wafer 100 may also have a rectangular or quadratic shape, or any other shape in general.

In the fabrication of integrated circuits (ICs), process control monitoring (PCM) may be carried out. PCM may be associated with designing and fabricating special structures (also referred to as PCM test structures) that can monitor technology specific parameters such as, for example, Vth (threshold voltage) in CMOS (complementary metal oxide semiconductor) technologies or Vbe (base-emitter voltage) in bipolar technologies. These structures may be placed across the wafer at specific locations along with the chip(s) produced so that a closer look into the process variation may be possible. PCM test structures usually may include one or more test devices (e.g. transistors) and associated pads (also referred to as PCM pads) to electrically contact the test device(s). In many cases, the pads may contain or may be made of a metal or a metal alloy such as, for example, copper (Cu), aluminum (Al), or an alloy containing Cu and/or Al (alternatively or in addition, other metals or metal alloys).

Oftentimes, PCM test devices and pads may be placed in the kerf region of a wafer, as is illustrated by FIG. 2.

FIG. 2 shows an enlarged view of a section of a wafer 200. The wafer 200 may be similar to the wafer 100 shown in FIG. 1, and the section shown in FIG. 2 may, for example, correspond to section “A” of the wafer 100 shown in FIG. 1. As illustrated in FIG. 2, one or more PCM test devices 104 and pads 102 may be placed in a kerf region 103 of the wafer 200 between adjacent die regions 101. The test devices 104 may be connected to the pads 102 to electrically contact the test devices 104.

Placing the PCM test structures in the kerf region of a wafer may have the effect that the test devices may be destroyed in a later dicing process. Thus, it may, for example, be possible to prevent that fully functional single devices will be delivered to the end customer, which might enable competitors to characterize the single devices. However, when dicing the wafer (for example, by means of sawing), cracks may occur at structures having large metal areas such as the PCM pads 102 shown in FIG. 2. Such cracks may result in chip failure out in the field on the customer's side. Thus, it may be desirable to provide an architecture that may avoid metal-induced crack formation during die singulation.

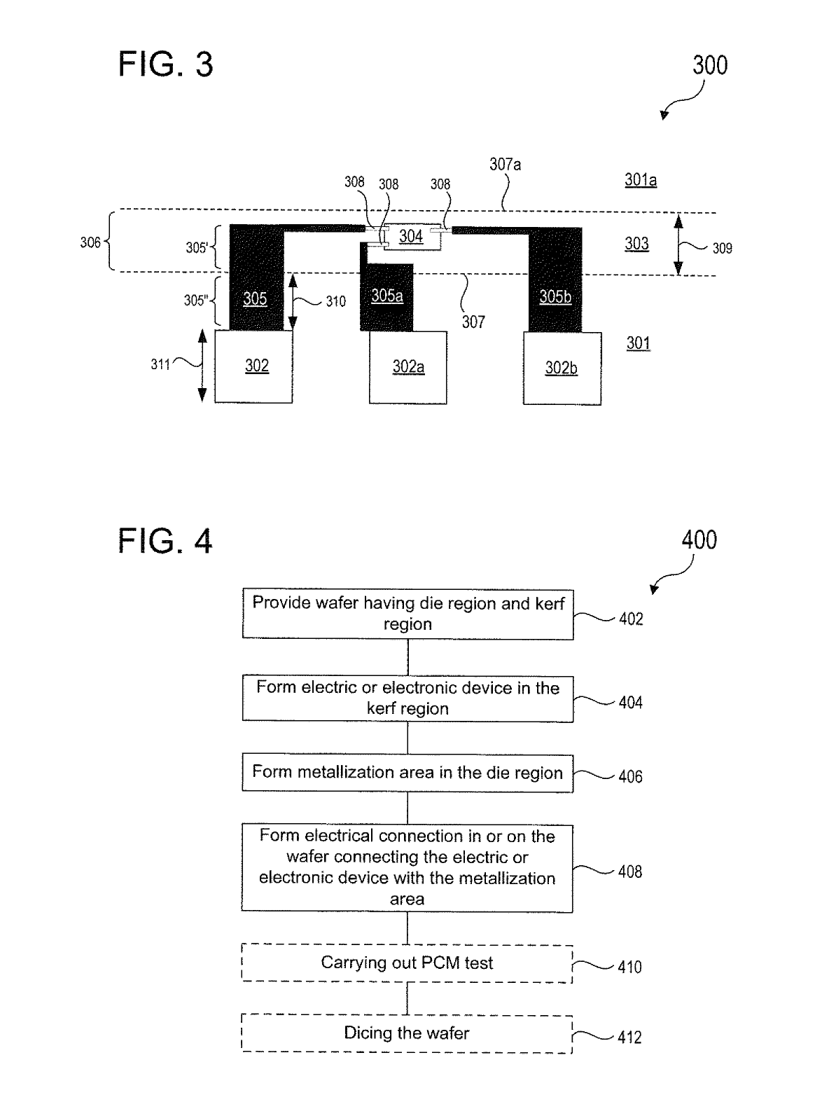

FIG. 3 shows, as a schematic plan view, a section of a wafer 300 in accordance with an embodiment. The wafer 300 may, for example, be a semiconductor wafer such as, for example, a silicon wafer (alternatively or in addition, any other suitable semiconductor material or materials, including compound semiconductor materials, may be used as well) in accordance with some embodiments.

In accordance with various embodiments, the wafer 300 may include a die region 301. In accordance with various embodiments, the die region 301 may correspond to the area of a die, which may be obtained from the wafer 300 by a die singulation or dicing process.

In accordance with some embodiments, the wafer 300 may include at least one additional die region 301a, as shown. In accordance with some embodiments, the at least one additional die region 301a may correspond to the area of at least one additional die that may be obtained from the wafer 300 by the die singulation or dicing process. In accordance with some embodiments, the at least one additional die region 301a may be configured in the same or a similar manner as the die region 301.

Clearly, in accordance with some embodiments, the wafer 300 may include a plurality of die regions (e.g. die regions 301, 301a and possibly additional die regions (not shown)) or integrally-formed dies. Thus, the wafer 300 may, for example, have a similar structure as the wafer 100 shown in FIG. 1 (for example, die regions 301, 301a may correspond to two neighboring die regions 101 of wafer 100 in FIG. 1), and the wafer 300 may later be diced (e.g. by sawing) to obtain single dies.

In accordance with various embodiments, the die region 301 may have a metallization area 302, as shown. In other words, a metallization area 302 may be located in the die region 301. In accordance with some embodiments, the metallization area 302 may, for example, be located in a peripheral region of the die region 301, for example proximate an edge of the die region 301. In accordance with some embodiments, the metallization area 302 may include or may be a pad. In accordance with some embodiments, the pad may contain or may be made of a metal or a metal alloy such as, for example, copper (Cu), aluminum (Al), or an alloy containing Cu and/or Al. Alternatively or in addition, the pad may contain or may be made of other metals or metal alloys.

In accordance with some embodiments, the metallization area 302 may be disposed on or above an upper surface of the wafer 300 in the die region 301.

In accordance with some embodiments, the die region 301 may have at least one additional metallization area 302a, 302b (a first additional metallization area 302a and a second additional metallization area 302b are shown as an example, however there may be only one additional metallization area or more than two additional metallization areas present in accordance with some embodiments). The additional metallization area(s) may be configured in the same or a similar manner as the metallization area 302, for example as pads.

In accordance with various embodiments, the wafer 300 may include a kerf region 303. The kerf region 303 may be located adjacent the die region 301.

The term “kerf region” as used herein may be understood to refer to a region of a wafer that may be at least partially removed or destroyed in a die singulation or dicing process. For example, in accordance with various embodiments, the kerf region 303 shown in FIG. 3 may illustratively include or correspond to one or more dicing streets or scribe lines 306 of the wafer 300 (in other words, a line or lines along which the wafer 300 may be diced (e.g. cut, e.g. by means of sawing)). In accordance with some embodiments, the kerf region 303 may be located at least partially between the die region 301 and at least one additional die region (e.g. the additional die region 301a, as shown in FIG. 3, and possibly other additional die regions (not shown)) of the wafer 300. For example, in accordance with some embodiments, the wafer 300 may include a plurality of die regions 301, 301a that may be separated by the kerf region 303 that may be formed between the die regions 301, 301a, e.g. similar to the wafer 100 shown in FIG. 1. The number of die regions of the wafer 300 may be arbitrary in accordance with various embodiments.

The die region 301 or the plurality of die regions of the wafer 300 may have any shape, for example a quadratic or rectangular shape in accordance with some embodiments, however any other shape may be possible as well in accordance with some embodiments.

In accordance with some embodiments, the die regions may be arranged in a rectangular array, e.g. similar to the array shown in FIG. 1. However, in accordance with other embodiments, the die regions may be arranged differently.

In accordance with various embodiments, the kerf region 303 may have at least one electric or electronic device 304 such as, for example, a resistor, and/or a capacitor, and/or a transistor, and/or other electric or electronic devices. In other words, one or more electric or electronic devices 304 may be located in the kerf region 303, as shown. In accordance with various embodiments, the dimensions of the device 304 (e.g. the width of the device) may be configured such that the device 304 may be fully accommodated in the kerf region 303.

In accordance with some embodiments, the at least one electric or electronic device 304 may include or may be a test device, for example a PCM (process control monitor) test device in accordance with some embodiments.

The term “test device” as used herein may be understood to refer to an electric or electronic component that may be used solely for testing in connection with a fabrication process, in contrast to e.g. other “operational devices” that might be used for testing as well, but may also be necessary or desirable for operation of a finished device. The distinction, therefore, may be seen in that a “test device” may be sacrificed or discarded after or at some point during fabrication. The test device or devices located in the kerf region 303, for example, may be destroyed during a die singulation or dicing process in accordance with various embodiments.

In accordance with various embodiments, the wafer 300 may include an electrical connection or connection region 305 connecting the electric or electronic device 304 with the metallization area 302, as shown.

In accordance with some embodiments, the electrical connection 305 may be disposed in the wafer, or on or above the upper surface of the wafer 300.

In accordance with various embodiments, the electrical connection 305 may be arranged such that a first part 305′ of the electrical connection 305 may be located in the kerf region 303, and a second part 305″ of the electrical connection 305 may be located in the die region 301, as shown. Illustratively, the electrical connection 305 may run from the device 304 located in the kerf region 303 to the metallization area 302 (e.g. metal pad) located in the die region 301, and a part of the electrical connection 305 may thus cross a boundary 307 between the kerf region 303 and the die region 301, as shown.

In accordance with some embodiments, the electrical connection 305 may be free from metal. The term “free from metal”, as used herein, may refer to electrically conductive materials other than a metal or metal alloy, and may include, for example, polysilicon, electrically conductive carbon, a doped semiconductor material (e.g. doped silicon), a silicide, a polycide, or other suitable electrically conductive materials that are not metals or metal alloys.

For example, in accordance with some embodiments, the electrical connection 305 may include or may be made of polysilicon. For example, in accordance with some embodiments, the electrical connection 305 may include or may be an electrically conductive trace made of polysilicon, which may be be formed in the wafer, or on or above the upper surface of the wafer 300.

In accordance with some embodiments, the electrical connection 305 may include or may be made of doped semiconductor material (e.g. doped silicon). For example, in accordance with some embodiments, the electrical connection 305 may include or may be a doped region formed in the wafer, for example a doped region located near the upper surface of the wafer. In accordance with some embodiments, the doped region may, for example, be a well region (e.g. a diffused well region) in the wafer.

In accordance with some embodiments, the wafer may include one or more additional electrical connections or connection regions connecting the electric or electronic device 304 with one or more additional metallization areas of the die region 301 and/or with one or more metallization areas of one or more additional die regions. In accordance with some embodiments, the additional electrical connection(s) may be configured in the same or a similar manner as the electrical connection 305. As an example, two additional electrical connections or connection regions 305a, 305b are shown in FIG. 3, connecting the device 304 with the additional metallization areas 302a, 302b. As shown in FIG. 3, a first additional electrical connection 305a may connect the device 304 with the first additional metallization area 302a (e.g. pad), and a second additional electrical connection 305b may connect the device 304 with the second additional metallization area 302b (e.g. pad) in accordance with some embodiments.

In accordance with some embodiments, the die region 301 may include one or more electric and/or electronic devices, or one or more integrated circuits (ICs) including one or more electric and/or electronic devices. The electric and/or electronic devices, or the integrated circuit(s), may, for example, be formed in an active region of the die region 301 in accordance with some embodiments.

In accordance with various embodiments, the metallization area 302 located in the die region 301 may be a pad associated with the electric or electronic device 304 (e.g. test device) located in the kerf region 303, for example a pad associated with a PCM test device in accordance with some embodiments.

In accordance with some embodiments, the one or more additional metallization areas (e.g. pads) 302a, 302b may also be associated or connected with the electric or electronic device 304 (e.g. test device) located in the kerf region 303.

In accordance with some embodiments, the electric or electronic device 304 (e.g. test device, e.g. PCM test device) located in the kerf region 303 may be connected with a plurality of metallization areas (e.g. pads, e.g. PCM pads), wherein at least one of the plurality of metallization areas may be located in one of the plurality of die regions (e.g. in the die region 301 shown in FIG. 3) and at least one other of the plurality of metallization areas may be located in another one of the plurality of die regions (e.g. in the additional die region 301a shown in FIG. 3). In other words, a plurality of metallization areas associated with the electric or electronic device 304 may be distributed over at least two of a plurality of die regions in accordance with some embodiments (not shown).

In accordance with some embodiments, the die region 301 may include one or more additional metallization areas (not shown), e.g. pads, that may be associated or connected with electric and/or electronic devices located in the die region 301.

As shown in FIG. 3, all the metallization areas 302, 302a, 302b may be located outside the kerf region 303 and may be connected to the device 304 located inside the kerf region 303 via the electrical connections 305, 305a, 305b. The electrical connections 305, 305a, 305b may be made of an electrically conductive material other than a metal or metal alloy, for example of polysilion in accordance with some embodiments. Thus, the kerf region 303 may be free from large metallization areas in accordance with various embodiments. In particular, edge regions (e.g. the boundary 307 between the kerf region 303 and the die region 301 and a boundary 307a between the kerf region 301 and the additional die region 301a, and possibly boundaries between the die region 301 and other additional die regions (not shown)) of the kerf region 303 or dicing street 306 may be free from metal in accordance with some embodiments.

In accordance with some embodiments, the electrical connection 305 may be connected to an electrical contact 308 (e.g. Met1 contact) of the device 304, as shown. Similarly, one or more of the additional electrical connections 305a, 305b (if present) may be connected to one or more additional electrical contacts 308a, 308b (e.g. Met1 contacts) of the device 304 in accordance with some embodiments.

In accordance with some embodiments, a width 309 of the kerf region 303, corresponding for example to a width of a dicing street 306 and/or corresponding to a distance between the die region 301 and an adjacent die region, e.g. the additional die region 301a as shown in FIG. 3, may, for example, be in the micrometer range, for example on the order of a few tens of a micrometer, e.g. about 50 μm in accordance with one embodiment, although it will be understood that, in general, the width 309 may e.g. depend on the process technology used so that other values of the width 309 may be possible as well in accordance with other embodiments.

In accordance with some embodiments, a distance 310 between the metallization area 305 (e.g. pad) and the kerf region 303 (similarly, distances between additional metallization areas 305a, 305b and the kerf region 303) may, for example, be in the micrometer range, for example on the order of a few tens of a micrometer, for example in the range from about 10 μm to about 50 μm in accordance with some embodiments, e.g. about 30 μm in accordance with one embodiment, although it will be understood that, in general, the distance 310 may e.g. depend on the process technology and other values of the distance 310 may be possible as well in accordance with other embodiments.

In accordance with some embodiments, a lateral dimension (e.g. length and/or width, or diameter) 311 of the metallization area 302 (similarly lateral dimensions of one or more of the additional metallization areas 302a, 302b) may, for example, be in the micrometer range, for example on the order of a few tens of a micrometer, e.g. about 50 μm in accordance with one embodiment, although it will be understood that, in general, the dimension 311 may e.g. depend on the process technology used and other values of the dimension 311 may be possible as well in accordance with other embodiments.

FIG. 4 shows a diagram illustrating a method 400 of processing a wafer in accordance with an embodiment.

In 402, a wafer may be provided. The wafer may have a die region and a kerf region. In accordance with some embodiments, the kerf region may be located adjacent the die region. In accordance with some embodiments, the wafer may have a plurality of die regions and the kerf region may be located at least partially between at least two of the plurality of die regions. The wafer, the die region or die regions, and/or the kerf region may further be configured in accordance with one or more embodiments described herein.

In 404, at least one electric or electronic device may be formed in the kerf region. In accordance with some embodiments, the at least one electric or electronic device may include or may be a test device, for example a PCM test device in accordance with some embodiments. In accordance with some embodiments, a plurality of electric or electronic devices may be formed in the kerf region. In accordance with some embodiments, at least one of the plurality of electric or electronic devices may include or may be a test device, e.g a PCM test device in accordance with some embodiments. The electric or electronic device or devices may further be configured in accordance with one or more embodiments desribed herein.

In 406, at least one metallization area may be formed in the die region. In accordance with some embodiments, the metallization area may be a pad, for example a PCM pad in accordance with some embodiments. The pad may contain or may be made of a metal or a metal alloy such as, for example, copper (Cu) or aluminum (Al), or an alloy containing Cu and/or Al. Alternatively or in addition, the pad may contain or may be made of other metals or metal alloys. In accordance with some embodiments, the metallization area (e.g. pad) may be formed in a peripheral region of the die region, for example, proximate (in other words, close to) a boundary between the kerf region and the die region. In accordance with some embodiments, a plurality of metallization areas, e.g. a plurality of pads, may be formed in the die region. The metallization area or areas may further be configured in accordance with one or more embodiments described herein.

In 408, an electrical connection may be formed in or on the wafer. The electrical connection may connect the electric or electronic device with the metallization area. The electrical connection may be free from metal. In other words, the electrical connection may be made of an electrically conductive material or materials other than a metal or metal alloy. For example, in accordance with some embodiments, the electrical connection may contain or may be made of polysilicon, electrically conductive carbon, a silicide, or a polycide. Alternatively, the electrical connection may contain or may be made of other electrically conductive materials. For example, in accordance with some embodiments, the electrical connection may be a doped semiconductor region in the wafer, e.g. a well region (e.g. diffused well region) in accordance with some embodiments. In accordance with some embodiments, a plurality of electrical connections may be formed in or on the wafer. The plurality of electrical connections may connect the electric or electronic device in the kerf region with a plurality of metallization areas (e.g. pads) in the die region. The electrical connection or connections may further be configured in accordance with one or more embodiments described herein.

In accordance with some embodiments, the at least one electric or electronic device may include or may be a PCM test device and the metallization area or areas may include or may be a PCM pad or pads, and at least one PCM test may be carried out after forming the electrical connection or connections using the PCM test device and PCM pad or pads, as shown in 410.

In accordance with some embodiments, the wafer may be diced (for example, by means of sawing) along the kerf region after forming the electrical connection or connections, as shown in 412. In accordance with some embodiments, the dicing may be carried out after a PCM test has been carried out. During the dicing, the kerf region of the wafer may be removed thereby obtaining one or more singulated dies. In accordance with various embodiments, the dicing may lead to the destruction of the electric or electronic device(s), e.g. the PCM test device(s), located in the kerf region. In accordance with various embodiments, crack formation at metallization areas may be substantially reduced or avoided as, for example, metallization areas (e.g. pads) associated with the electric or electronic device(se), e.g. the PCM test device(s) in the kerf region, may be located in the die region(s) and thus outside the kerf region. Thus, the kerf region, or at least edges of the kerf region, may be substantially or completely free from metal or metal alloys.

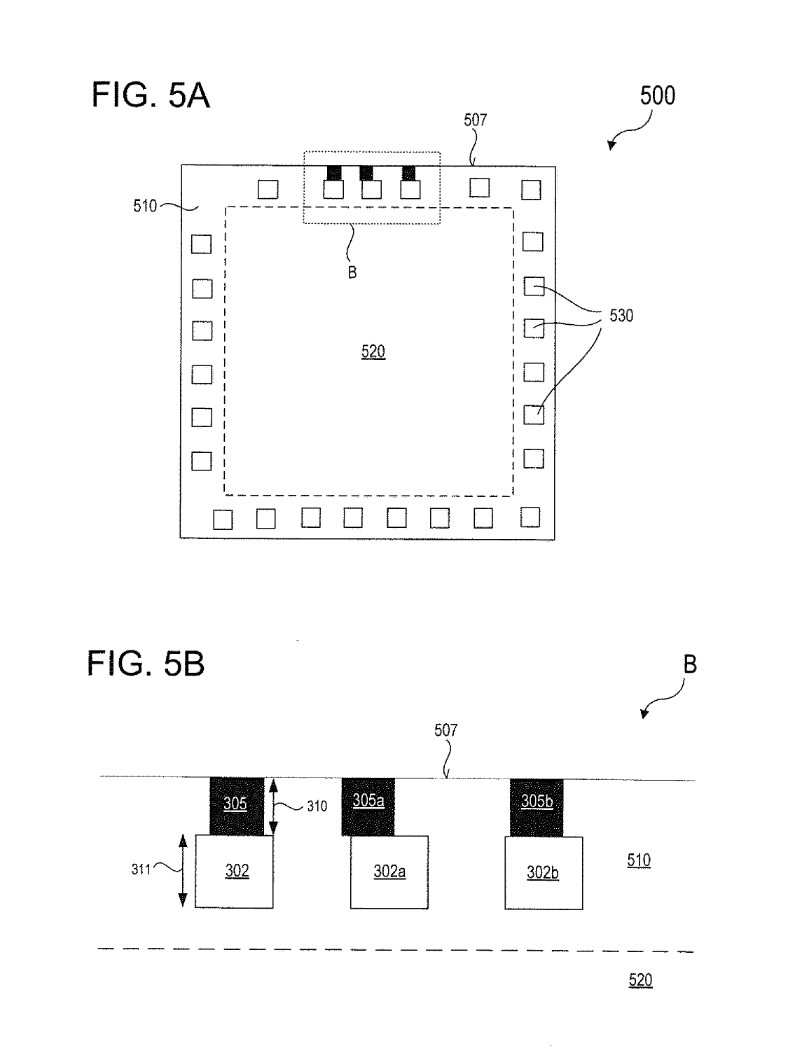

FIG. 5A and FIG. 5B are schematic views for illustration of a die in accordance with an embodiment.

FIG. 5A shows a schematic plan view of a die 500 in accordance with an embodiment, and FIG. 5B shows an enlarged view of section “B” of the die 500 shown in FIG. 5A.

Illustratively, the die 500 may be obtained by dicing the wafer 300 shown in FIG. 3 along the kerf region 303 (for example, using a saw), thereby removing the material of the kerf region 303 (including the device(s) 304 and those parts of the electrical connections 305, 305a, 305b located in the kerf region 303). In other words, the area of die 500 may illustratively correspond to the die region 301 of wafer 300 shown in FIG. 3, and the same reference numerals denote the same elements as in FIG. 3.

The die 500 may include metallization areas 302, 302a, 302b located proximate an edge 507 of the die 500. Three metallization areas 302, 302a, 302b are shown as an example and corresponding to the embodiment shown in FIG. 3. However, in accordance with other embodiments, the die 500 may include only one or only two metallization areas, or may include more than three metallization areas. The edge 507 of the die 500 may correspond to the boundary 307 between the kerf region 303 and the die region 301 of wafer 300 in FIG. 3. In accordance with some embodiments, the metallization areas 302, 302a, 302b may be located in a peripheral region 510 of the die 500, as shown. In accordance with some embodiments, the die 500 may include one or more electric and/or electronic devices, e.g. one or more integrated circuit elements, such as resistors, capacitors, transistors, diodes, thyristors, etc., (not shown), that may, for example be located in an active region 520 of the die 500.

The die 500 may include electrical connection 305 connected to metallization area 302 and running from metallization area 302 to the edge 507. As described above, the electrical connection 302 may be free from metal. Similarly, in accordance with some embodiments, the die 500 may include additional electrical connections 305a, 305b connected to additional metallization areas 302a, 302b, as shown.

Illustratively, the die 500 may include one or more metallization areas 302, 302a, 302b (e.g. one or more pads, e.g. PCM pads) that may be located in a peripheral region 510 of the die 500 proximate the edge 507, and an electrical connection 305, 305a, 305b (e.g. an electrically conductive trace formed in the die 500, or on or above the upper surface of the die 500 and e.g. containing or being made of polysilicon, alternatively another electrically conductive material other than a metal or metal alloys; or a doped region (e.g. a well region, e.g. a diffused well region) in the die 500, e.g. near the upper surface of the die 500) may in each case lead from the respective metallization area 302, 302a, 302b towards the edge 507 of the die 500 and may terminate at or close to the edge 507 of the die 500, as shown.

Clearly, the edge 507 may have been obtained by dicing (e.g. sawing) the wafer 300 along the kerf region 303 or dicing street 306. Thus, in accordance with various embodiments, the one or more electrical connections 305, 305a, 305b may terminate at or close to a sawing edge of the die 500.

In accordance with some embodiments, the die 500 may include one or more additional metallization areas 530 (e.g. pads) that may, for example, be located in the peripheral region 510 of the die 500, as shown. In accordance with some embodiments, the metallization area(s) 530 (e.g. pad(s)) may serve to electrically contact the one or more electric and/or electronic devices of the die 500 located in the active region 520 of the die 500. Clearly, the metallization areas 302, 302a, 302b (e.g. pads) may differ from the additional metallization area(s) 530 in that the metallization areas 302, 302a, 302b may have been formed and/or configured to electrically contact electric or electronic devices (e.g. PCM test devices) located in a kerf region of a wafer (e.g. kerf region 303 of wafer 300), which may be no longer present after dicing the wafer, whereas the additional metallization areas (e.g. pads) 530 may have been formed or configured to electrically contact one or more electric or electronic devices of the die 500 (for example, operational devices of the die 500 that may be used for operation of the die 500) located, for example, in the active region 520 of the die 500. Thus, in accordance with various embodiments, the additional metallization areas (e.g. pads) 530 may be connected to one or more electric or electronic devices of the die 500 while the metallization areas 302, 302a, 302b may be not connected to any of the electric or electronic devices of the die 500. For example, the electrical connection 305 may be the only electrical connection connected to the metallization area 302 in accordance with some embodiments. Similarly, the electrical connection 305a may be the only electrical connection connected to the metallization area 302a and the electrical connection 305b may be the only electrical connection connected to the metallization area 302b in accordance with some embodiments.

A die in accordance with various embodiments may include a metallization area located proximate an edge of the die; and an electrical connection connected to the metallization area and running from the metallization area to the edge, wherein the electrical connection is free from metal.

In accordance with various embodiments, the electrical connection may terminate at or close to the edge.

In accordance with some embodiments, the electrical connection may include an electrically conductive trace formed in the die, or on or above an upper surface of the die.

In accordance with some embodiments, the electrical connection may contain or may be made of polysilicon.

In accordance with some embodiments, the electrical connection may contain or may be made of carbon.

In accordance with some embodiments, the electrical connection may contain or may be made of a silicide.

In accordance with some embodiments, the electrical connection may contain or may be made of a polycide.

In accordance with some embodiments, the electrical connection may include or may be a doped region formed in the die, for example near an upper surface of the die.

In accordance with some embodiments, the doped region may be a well region, e.g. a diffused well region, in the die.

In accordance with some embodiments, the metallization area may include or may be a pad, for example a process control monitor (PCM) pad in accordance with an embodiment. The pad may contain or may be made of a metal or a metal alloy such as, for exampel, copper (Cu) or aluminum (Al), or an alloy containing Cu and/or Al. Alternatively or in addition, the pad may contain or may be made of other metals or metal alloys.

A wafer in accordance with various embodiments may include: a die region having a metallization area; a kerf region having an electric or electronic device; and an electrical connection connecting the electric or electronic device with the metallization area, wherein the electrical connection is free from metal.

In accordance with various embodiments, the kerf region may correspond to a region of the wafer to be removed in a dicing process.

In accordance with some embodiments, the kerf region may be located adjacent to the die region.

In accordance with some embodiments, the metallization area may be located in a peripheral region of the die region.

In accordance with some embodiments, the metallization area may be located proximate a boundary between the kerf region and the die region.

In accordance with some embodiments, the electrical connection may include or may be an electrically conductive trace formed in the wafer, or on or above an upper surface of the wafer.

In accordance with some embodiments, the electrical connection may contain or may be made of polysilicon.

In accordance with some embodiments, the electrical connection may contain or may be made of carbon.

In accordance with some embodiments, the electrical connection may contain or may be made of a silicide.

In accordance with some embodiments, the electrical connection may contain or may be made of a polycide.

In accordance with some embodiments, the electrical connection may include or may be a doped region formed in the wafer, for example located near an upper surface of the wafer.

In accordance with some embodiments, the doped region may be a well region, e.g. a diffused well region, in the wafer.

In accordance with some embodiments, the metallization area may include or may be a pad, e.g. a process control monitor (PCM) pad. The pad may, for example, contain or be made of a metal or a metal alloy such as, for example, copper (Cu) or aluminum (Al), or an alloy containing Cu and/or Al. Alternatively or in addition, the pad may contain or may be made of other metals or metal alloys.

In accordance with some embodiments, the electric or electronic device may include or may be a test device.

In accordance with some embodiments, the test device may be a process control monitor (PCM) test device.

In accordance with some embodiments, the wafer may include at least one additional die region, and the kerf region may be located at least partially between the die region and the at least one additional die region.

In accordance with some embodiments, the wafer may include a plurality of die regions, and the kerf region may be located between the plurality of die regions.

A wafer in accordance with various embodiments may include: a die region having a pad; a kerf region having a test device; an electrical connection connecting the test device in the kerf region with the pad in the die region, the electrical connection being made of an electrically conductive material other than a metal or metal alloy.

In accordance with some embodiments, the test device may include or may be a process control monitor (PCM) test device.

In accordance with some embodiments, the electrical connection may contain or may be made of polysilicon.

In accordance with some embodiments, the electrical connection may contain or may be made of carbon.

In accordance with some embodiments, the electrical connection may contain or may be made of a silicide.

In accordance with some embodiments, the electrical connection may contain or may be made of a polycide.

In accordance with some embodiments, the pad may contain or may be made of a metal or a metal alloy such as, for example, copper (Cu) or aluminum (Al), or an alloy containing Cu and/or Al. Alternatively or in addition, the pad may contain other metals or metal alloys.

A wafer in accordance with various embodiments may include: a plurality of integrally-formed dies separated from each other by a kerf region formed between them, at least one of the plurality of dies having at least one process control monitor (PCM) pad containing metal or a metal alloy; at least one PCM test device located in the kerf region and electrically connected to the at least one PCM pad via at least one electrical connection that is free from metal.

In accordance with some embodiments, the at least one electrical connection may include or may be an electrically conductive trace containing or being made of polysilicon and formed in the wafer or on or above an upper surface of the wafer.

In accordance with some embodiments, the at least one electrical connection may include or may be a doped region, e.g. a well region, e.g. a diffused well region, formed in the wafer.

A method of processing a wafer in accordance with various embodiments may include: providing a wafer having a die region and a kerf region; forming an electric or electronic device in the kerf region; forming a metallization area in the die region; forming an electrical connection in or on the wafer connecting the electric or electronic device with the metallization area, the electrical connection being free from metal.

In accordance with some embodiments, the electrical connection may contain or may be made of polysilicon.

In accordance with some embodiments, the electrical connection may contain or may be made of carbon.

In accordance with some embodiments, the electrical connection may contain or may be made of a silicide.

In accordance with some embodiments, the electrical connection may contain or may be made of a polycide.

In accordance with some embodiments, the method may further include: dicing the wafer along the kerf region after forming the electrical connection.

In accordance with some embodiments, dicing the wafer along the kerf region may include or may be achieved by sawing the wafer along the kerf region.

In accordance with some embodiments, the electric or electronic device may include or may be a process control monitor (PCM) test device, and the method may further include: carrying out a PCM test using the PCM test device after forming the electrical connection and before dicing the wafer.

A method of processing a wafer in accordance with various embodiments may include: providing a wafer, the wafer having a plurality of integrally-formed dies separated from each other by a kerf region formed between them, at least one of the plurality of dies having at least one pad containing or being made of a metal or a metal alloy, the wafer further having at least one process control monitor (PCM) test device formed in the kerf region and connected to the at least one pad via at least one electrical connection, the at least one electrical connection being free from metal; and dicing the wafer along the kerf region.

In accordance with some embodiments, dicing the wafer along the kerf region may include or may be achieved by sawing the wafer along the kerf region.

In accordance with some embodiments, the at least one electrical connection may include or may be made of polysilicon.

A wafer in accordance with various embodiments may include a plurality of dies; a scribe line formed between at least two dies of the plurality of dies and having at least one test device; at least one electrical connection connecting the test device in the scribe line with at least one pad of at least one die of the at least two dies, the at least one electrical connection being made of an electrically conductive material other than a metal or metal alloy.

In accordance with some embodiments, the at least one pad may contain or may be made of a metal or a metal alloy such as, for example, copper (Cu) or aluminum (Al), or an alloy containing Cu and/or Al. Alternatively or in addition, the at least one pad may contain or may be made of other metals or metal alloys.

In accordance with some embodiments, the at least one test device may include or may be a PCM (process control monitor) test device.

The wafer, or parts of the wafer, may further be configured in accordance with one or more embodiments described herein.

A wafer in accordance with various embodiments may include: a plurality of dies separated by a plurality of scribe lines; a plurality of PCM test devices located in the scribe lines and connected to a plurality of PCM pads of the plurality of dies by a plurality of electrical wirings containing polysilicon.

In accordance with some embodiments, the PCM pads may contain or may be made of a metal or a metal alloy such as, for example, copper (Cu) or aluminum (Al), or an alloy containing Cu and/or Al. Alternatively or in addition, the pads may contain or may be made of other metals or metal alloys.

In accordance with some embodiments, edges of the scribe lines located near or adjacent the dies may be free from metal.

The wafer, or one or more parts of the wafer, may further be configured in accordance with one or more embodiments described herein.

A wafer in accordance with various embodiments may include: a kerf region; an electric or electronic device in the kerf region; a metallization area outside the kerf region; an electrical connection connecting the electric or electronic device with the metallization area, the electrical connection being free from metal.

In accordance with some embodiments, the metallization area may include or may be a pad, e.g. a PCM pad.

In accordance with some embodiments, the electric or electronic device may include or may be a test device, e.g. a PCM test device.

In the following, exemplary features and potential effects of exemplary embodiments described herein are discussed.

In accordance with various embodiments, a new architecture for PCM/kerf structures may be provided that may, for example, reduce or prevent crack formation during die singulation.

In accordance with various embodiments, one or more electric or electronic devices, e.g. test devices such as PCM test devices, may be placed in the kerf region (or scribe line) of a wafer while associated pads (e.g. PCM pads) may be placed outside the kerf region (scribe line). In accordance with various embodiments, the devices may be connected with the pads by means of one or more electrical connections that are free from metal. In other words, the electrical connection or connections may be made of a material or materials other than a metal or metal alloy. For example, in accordance with some embodiments, the electrical connection(s) may include or may be made of polysilicon or other suitable electrically conductive materials such as e.g. carbon, a silicide, a polycide, or doped semiconductor material (e.g. doped silicon) of the wafer.

In contrast to conventional architectures where PCM test devices and associated pads are placed in the kerf region or scribe line(s) (see FIG. 2), in the new architecture in accordance with various embodiments the PCM test devices may still be located in the kerf region or scribe line while the associated PCM pads may be located completely outside the kerf region or scribe line(s), and the wiring between the PCM test devices and PCM pads may be realized by an electrically conductive material other than a metal or metal alloys, for example polysilicon. Illustratively, the wiring may cross the boundary between the kerf region (scribe line) and one or more adjacent die regions.

This may, for example, have the effect that, on the one hand, the PCM devices may still be removed in a dicing process (e.g. sawing process), which may prevent that fully functional single devices will be delivered to the end customer (which might enable competitors to characterize the single devices), while, on the other hand, metal-induced crack formation during dicing may be reduced or prevented since the PCM pads may be located outside the kerf region or scribe line(s) so that the kerf region or scribe line(s) may be substantially free from metal.

In accordance with various embodiments, PCM test devices may still be located in the kerf region or dicing street(s) and removed later in the dicing process (e.g. sawing process), while the electrical connection (e.g. wiring) from the critical region (i.e. the dicing street(s) or region(s) affected, e.g. destroyed, by the dicing) to one or more associated pads may be realized with electrically conductive material other than a metal or metal alloy (e.g. polysilicon) and the pads may lie entirely outside the dicing street(s).

In accordance with various embodiments, the kerf region or dicing streets of a wafer may be kept free or substantially free from metal by placing comparatively large metallization areas such as e.g. PCM pads outside the kerf region. Thus, potential crack formation at metallization areas in the kerf region or dicing streets may be reduced or avoided. Furthermore, in accordance with various embodiments, PCM test devices may still be placed in the kerf region or dicing streets and may be removed or destroyed in a later dicing process. Thus, it may be prevented that fully functional single devices will be delivered to the end customer, as would be the case if the PCM test devices were placed outside the kerf region in the die regions. Furthermore, wafers in accordance with various embodiments may save wafer area compared e.g. to a wafer having one or more block PCMs (i.e. a wafer where one or more of the die regions (e.g. one or more of the die regions 101 in FIG. 1) will be spared for forming a plurality of PCM test structures as a block and will be discarded after the dicing of the wafer).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A die, comprising:
a metallization area located proximate an edge of the die;
an electrical connection connected to the metallization area and running from the metallization area to the edge, wherein the electrical connection is free from metal.

2. The die of claim 1,
wherein the electrical connection comprises an electrically conductive trace disposed in the die, or on or above an upper surface of the die.

3. The die of claim 2,
wherein the electrical connection comprises polysilicon.

4. The die of claim 1,
wherein the electrical connection comprises a doped region formed in the die.

5. The die of claim 1,
wherein the metallization area comprises a pad.

6. A wafer, comprising:
a die region comprising a metallization area;
a kerf region comprising an electric or electronic device;
an electrical connection connecting the electric or electronic device with the metallization area, wherein the electrical connection is free from metal.

7. The wafer of claim 6,
wherein the electrical connection comprises an electrically conductive trace disposed in the wafer, or on or above an upper surface of the wafer.

8. The wafer of claim 7,
wherein the electrical conductive trace comprises polysilicon.

9. The wafer of claim 6,
wherein the electrical connection comprises a doped region formed in the wafer.

10. The wafer of claim 6,
wherein the metallization area comprises a pad.

11. The wafer of claim 6,
wherein the electric or electronic device comprises a test device.

12. The wafer of claim 11,
wherein the test device is a process control monitor (PCM) test device.

13. A wafer comprising:
a die region comprising a pad;
a kerf region comprising a test device;
an electrical connection connecting the test device in the kerf region with the pad in the die region, the electrical connection being made of an electrically conductive material other than a metal or metal alloy.

14. The wafer of claim 13,
wherein the test device is a process control monitor (PCM) test device.

15. The wafer of claim 13,
wherein the pad comprises a metal or a metal alloy.

16. A wafer, comprising:
a plurality of integrally-formed dies separated from each other by a kerf region formed between them, at least one of the plurality of dies comprising at least one process control monitor (PCM) pad comprising a metal or a metal alloy;
at least one PCM test device located in the kerf region and electrically connected to the at least one PCM pad via at least one electrical connection that is free from metal.

17. The wafer of claim 16,
wherein the at least one electrical connection comprises an electrically conductive trace comprising polysilicon and disposed in the wafer or on or above an upper surface of the wafer.

18. The wafer of claim 16,
wherein the at least one electrical connection comprises a doped region formed in the wafer.

19. A method of processing a wafer, the method comprising:
providing a wafer having a die region and a kerf region;
forming an electric or electronic device in the kerf region;
forming a metallization area in the die region;
forming an electrical connection in or on the wafer connecting the electric or electronic device with the metallization area, the electrical connection being free from metal.

20. The method of claim 19,
wherein the electrical connection comprises polysilicon.

21. The method of claim 19, further comprising:
dicing the wafer along the kerf region after forming the electrical connection.

22. The method of claim 21, wherein the electric or electronic device comprises a process control monitor (PCM) test device and the metallization area comprises a PCM pad, the method further comprising:
after forming the electrical connection and before dicing the wafer, carrying out a PCM test using the PCM test device and the PCM pad.
